(19) United States
(12) Patent Application Publication
(10) Pub. No.: US 2011/0277963 A1
(43) Pub. Date: Nov. 17, 2011

(54) THERMAL MODULE AND METHOD OF MANUFACTURING THE SAME

(75) Inventors: YAU-HUNG CHIOU, Taipei (TW); SHU-HUI FAN, Taipei (TW); YUAN-LI CHUANG, Banqiao (TW)

(73) Assignee: CHENMING MOLD IND. CORP., Taipei (TW)

(21) Appl. No.: 12/778,147

(22) Filed: May 12, 2010

(51) Int. Cl. H01L 23/36; H01L 23/467; B21D 53/02; H01L 23/427

(52) U.S. Cl. 165/104.26; 165/185; 165/121; 29/890.03

(57) ABSTRACT

A thermal module and a method of manufacturing the same are disclosed. The thermal module includes a first heat dissipation member, a second heat dissipation member, a binding layer, and a metal layer. The first heat dissipation member can be a heat dissipating substrate, and the second heat dissipation member can be a heat pipe or a heat dissipating substrate. The metal layer is coated on the first heat dissipation member through a metal spray process. The binding layer can be a solder paste. By providing the spray-coated metal layer, the thermal module can have upgraded heat dissipation efficiency, increased pull strength, and reduced manufacturing cost.

### FIELD OF THE INVENTION

The present invention relates to a thermal module and a method of manufacturing the same; and more particularly, to a thermal module and a method of manufacturing the same, in which a metal layer is formed through a metal spray process to bind a first and a second heat dissipation member.

### BACKGROUND OF THE INVENTION

With the constant development in the electronic industrial field, various kinds of integrated circuit chips, such as the central processing unit, the memory, and different control chips, can be now manufactured with upgraded processes. As a result, the number of chips that can be provided within the same unit volume is larger than before, and the chip package area is smaller than before; meanwhile, these integrated circuit chips have higher operation clock pulse than before to obtain the effect of quicker computing ability. However, these chips would produce heat when they operate, and the heat produced within one unit area is much higher than before due to the reduced chip area and increased operation clock pulse. The produced heat energy would lead to rising of chip temperature. When the temperature exceeds the allowable working temperature of the chips, problems such as unstable system operation or even burnout of system might occur.

One way adopted by the electronic industrial field to solve the above problems is to particularly mount a thermal module on any electronic element that produces relatively high amount of heat. With the thermal module, heat produced by the electronic element can be removed therefrom and dissipated into external environment to thereby reduce the temperature of the electronic element. The thermal module can be assembled from a substrate having radiating fins provided thereon, at least one heat pipe provided on the radiating fins, and a cooling fan. Portions of the substrate for connecting to the heat pipe are first coated with a layer of electroplated nickel. To do so, only the portions to be electroplated are immersed in an electrolyte solution. Then, a layer of solder paste is applied on the connection portions, and the heat pipe is connected to the substrate via the solder paste. Finally, the assembled thermal module is positioned in a high-temperature oven for sintering the solder paste. When the solder paste is molten, the thermal module is removed from the oven and positioned in a room-temperature or low-temperature environment for the solder paste to cool and set and accordingly, connect the substrate to the heat pipe.

However, the conventional nickel electroplating process has the following disadvantages:

(1) The nickel electroplating process must be performed in an acid electrolyte solution and is therefore a wet process, which would produce environmentally hazardous chemicals and does not satisfy the increasingly strict codes for environmental protection.

(2) In most cases, the electroplating process is a whole electroplating process instead of a localized electroplating process, because the latter tends to result in further increased manufacturing cost.

(3) Nickel has thermal conductivity of about 73.3 W/(m·k), which is far lower than that of aluminum and copper. Therefore, the electroplated nickel would cause reduction of thermal conductivity value in the heat transfer path of the thermal module and accordingly result in lowered heat dissipation performance of the whole thermal module.

(4) The binding ability between nickel and copper as well as aluminum is relatively low. Thus, the electroplated nickel layer provided between the substrate and the heat pipe would lead to lowered heat transfer effect.

### SUMMARY OF THE INVENTION

A primary object of the present invention is to provide a thermal module and a method of manufacturing the same, so as to solve the problems in the prior art thermal module, including high manufacturing cost, insufficient binding ability and reduced heat conductivity value, which are caused by binding a first and a second heat dissipation member, that is, the substrate and the heat pipe, via an electroplated nickel in an attempt to achieve necessary heat transfer ability.

To achieve the above and other objects, the thermal module provided according to the present invention includes a first heat dissipation member, a second heat dissipation member and a metal layer. The metal layer is provided between the first and the second heat dissipation layer and has a thickness ranged between 1 μm and 1000 μm.

Preferably, the first heat dissipation member is a heat dissipating substrate.

Preferably, the second heat dissipation member is a heat dissipation substrate or a heat pipe.

Preferably, a binding layer is further provided between the second heat dissipation member and the metal layer for binding the second heat dissipation member to the metal layer. In the present invention, the binding layer is a solder paste.

Preferably, the metal layer is formed of a copper metal material, a copper alloy, a nickel metal material, a nickel alloy, or a copper-nickel alloy.

And, to achieve the above and other objects, the method of manufacturing a thermal module provided according to the present invention includes the following steps: First, providing a first heat dissipation member; then, forming a metal layer on the first heat dissipation member via a metal spray process; thereafter, providing a binding layer on one side of the metal layer; and finally, providing a second heat dissipation member on one side of the binding layer, so that the first and the second heat dissipation member are bound to each other via the metal layer and the binding layer.

According to the method of the present invention, the metal spray process can be vacuum plasma spray (VPS), arc melting spray, wire flame spray, powder flame spray, high velocity oxygen-fuel (HOW) spray, or atmosphere plasma spray (APS).

According to the method of the present invention, the metal layer has a thickness ranged between 1 μm and 1000 μm.

Preferably, the first heat dissipation member is a heat dissipating substrate.

Preferably, the heat dissipating substrate is made of an aluminum metal material.

Preferably, the second heat dissipation member is a heat dissipation substrate or a heat pipe.

Preferably, the metal layer is formed of a copper metal material, a copper alloy, a nickel metal material, a nickel alloy, or a copper-nickel alloy.

With the thermal module and the manufacturing method thereof according to the present invention, the metal layer for binding the first and the second heat dissipation member to each other is formed on the first heat dissipation member by way of a metal spray process, which enables the thermal module to be manufactured at reduced cost and have increased heat transfer efficiency, and enables an upgraded binding ability between the first and the second heat dissipation member.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a first embodiment of a thermal module according to the present invention;

FIG. 2 is a cross sectional view taken along line A-A′ of FIG. 1;

FIG. 3 is a perspective view of a second embodiment of the thermal module according to the present invention;

FIG. 4 is a cross sectional view taken along line B-B′ of FIG. 3; and

FIG. 5 is a flowchart showing the steps included in a method of manufacturing a thermal module according to the present invention.

### DETAILED DESCRIPTION OF THE PREFERRED EMBODIMENTS

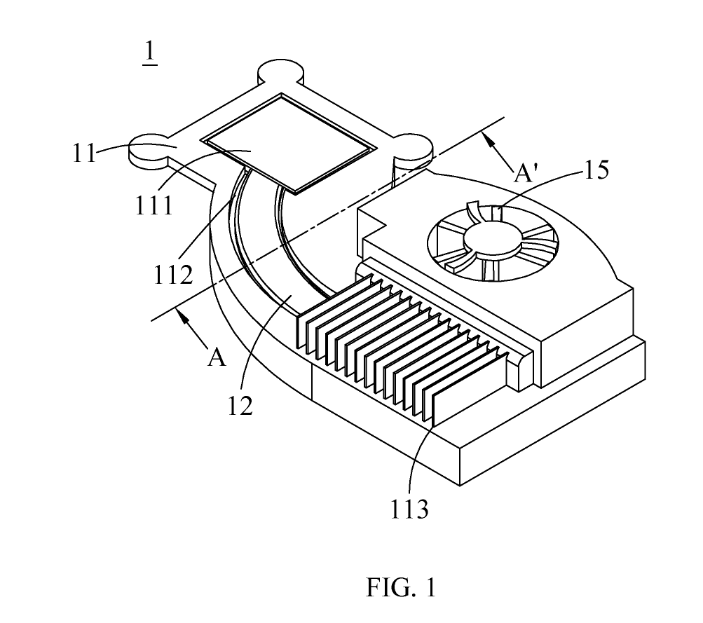

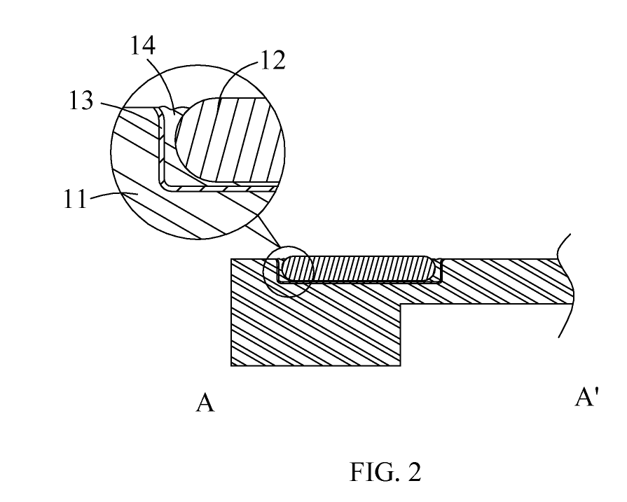

Please refer to FIG. 1 that is a perspective view of a first embodiment of a thermal module according to the present invention, and to FIG. 2 that is a cross sectional view taken along line A-A′ of FIG. 1. As shown, the first embodiment of the thermal module according to the present invention is generally denoted by reference numeral 1, and includes a first heat dissipation member 11, a second heat dissipation member 12, a metal layer 13, and a binding layer 14.

The first heat dissipation member 11 can be a heat dissipating substrate made of an aluminum metal material. An end of the first heat dissipation member 11 is provided with a contact section 111, on which an electronic element (not shown), such as a central processing unit (CPU), a graphics chipset, a south bridge chip, a north bridge chip, or any other control chips, can be disposed. Further, depending on actual need, the first heat dissipation member 11 can be provided with a groove 112 corresponding to the second heat dissipation member 12. For the purpose of enhanced heat dissipation performance, the first heat dissipation member 11 can be additionally provided with a radiating fin assembly 113 depending on actual need. The metal layer 13 can be formed of a copper metal material, a copper alloy material, a nickel metal material, a nickel alloy material, or a copper-nickel alloy material. The metal layer 13 is formed on one side of the first heat dissipation member 11 by way of a metal spray process. For example, the metal layer 13 can be coated on one side of the first heat dissipation member 11 by vacuum plasma spray, arc melting spray, wire flame spray, powder flame spray, high velocity oxygen-fuel spray, or atmosphere plasma spray, so that a coating about 1 μm to 1000 μm in thickness is formed.

The binding layer 14 can be formed of a low-temperature solder paste having, but not limited to, a working temperature ranged between 120° C. and 220° C. After the metal layer 13 has been formed on the first heat dissipation member 11 by the metal spray process, the low-temperature solder paste is applied over the metal layer 13 to form the binding layer 14.

The second heat dissipation member 12 can be a heat pipe, which is a round heat pipe made of a copper material usually having, but not limited to, a diameter from 6 mm to 8 mm, and is bent and flattened using a mold or a tool for burying in the groove 112 to locate above the binding layer 14. The heat pipe has a vacuum internal space and contains a small amount of water vapor or condensed water. A first end of the heat pipe is a vaporizing end located at the contact section 111 of the first heat dissipation member 11, and an opposite second end of the heat pipe is a condensing end located at one side of the radiating fin assembly 113. Via the vaporization and condensation of water vapor in the heat pipe, heat produced by the electronic element disposed on the contact section 111 of the first heat dissipation member 11 can be quickly transferred to the radiating fin assembly 113 via the heat pipe.

When the thermal module 1 is fully assembled, the first and the second heat dissipation member 11, 12 that have not yet been bound to each other via tin solder can be clamped together using a fixture or other clamping device before the thermal module 1 is sent to and baked in a high-temperature oven. In the oven, the solder paste forming the binding layer 14 is heated to a molten state to cover and connect the first heat dissipation member 11 to the second heat dissipation member 12. When the thermal module 1 is removed out of the high-temperature oven, let the thermal module 1 stay still under room temperature for a predetermined time period until the solder paste is set. At this point, the first heat dissipation member 11 and the second heat dissipation member 12 are indirectly bound together via the metal layer 13 and the solder paste to complete the process of binding the first and second heat dissipation members 11, 12 to each other.

To enable more effectively upgraded heat dissipation efficiency, a cooling fan 15 can be provided to one side of the first heat dissipation member 11 for blowing the heat energy accumulated on the radiating fin assembly 113 into external environment to achieve the purpose of active cooling.

The metal spray process for coating the metal layer 13 on the first heat dissipation member 11 is a dry process and therefore produces less environmentally hazardous pollutants in the process of forming the metal layer 13. In addition, as having been mentioned above, the metal layer 13 can be formed of a copper metal material or a nickel-aluminum alloy material. Since copper and aluminum have a heat conductivity value about 386 W/(m·k) and 220 W/(m·k), respectively, which are higher than the heat conductivity value of 73.3 W/(m·k) of the conventional electroplated nickel material, the metal layer 13 used in the present invention is able to give the thermal module 1 an upgraded overall heat transfer ability. Moreover, in the metal spray process, portions on the first heat dissipation member 11 that are not to be coated with the metal layer can be easily covered using a simple masking device at a cost lower than that for a localized electroplating process. Further, since copper metal material or copper-nickel metal material has metal binding ability higher than that of the conventional electroplated nickel, the metal layer of the present invention can have upgraded heat transfer ability and pull strength to thereby enable the whole thermal module to have increased reliability in use.

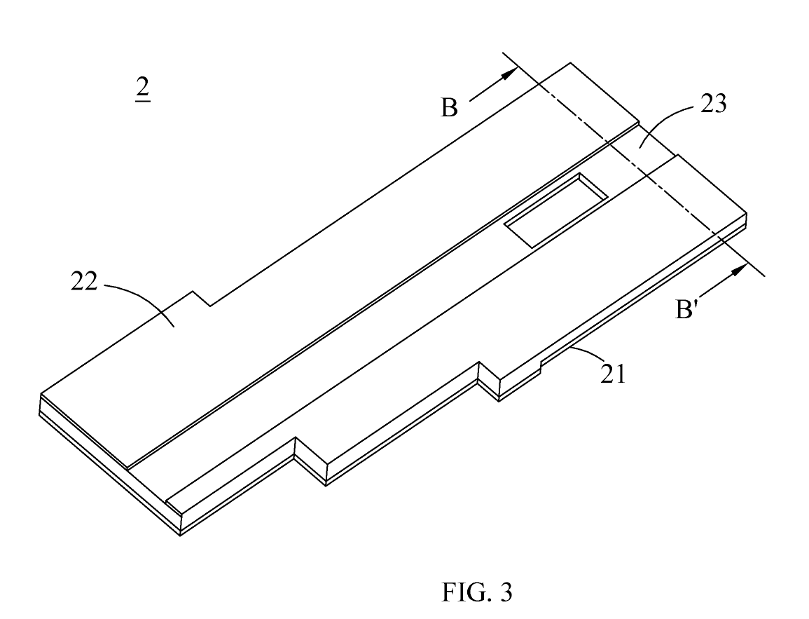

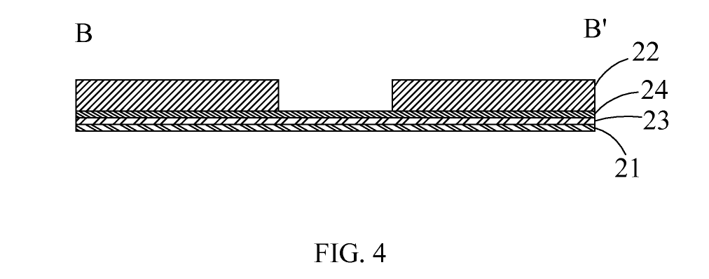

Please refer to FIG. 3 that is a perspective view of a second embodiment of the thermal module according to the present invention; and to FIG. 4 that is a cross sectional view taken along line B-B′ of FIG. 3. As shown, the second embodiment of the thermal module according to the present invention is generally denoted by reference numeral 2, and includes a first heat dissipation member 21, a second heat dissipation member 22, a metal layer 23, and a binding layer 24. In the second embodiment, since the first heat dissipation member 21, the metal layer 23, and the binding layer 24 are similar to those in the first embodiment, they are not repeatedly described herein. The second embodiment is different from the first embodiment in that the second heat dissipation member 22 includes two heat dissipation substrates, which can be spaced from each other and bound to the first heat dissipation member 21 via the metal layer 23 and the binding layer 24.

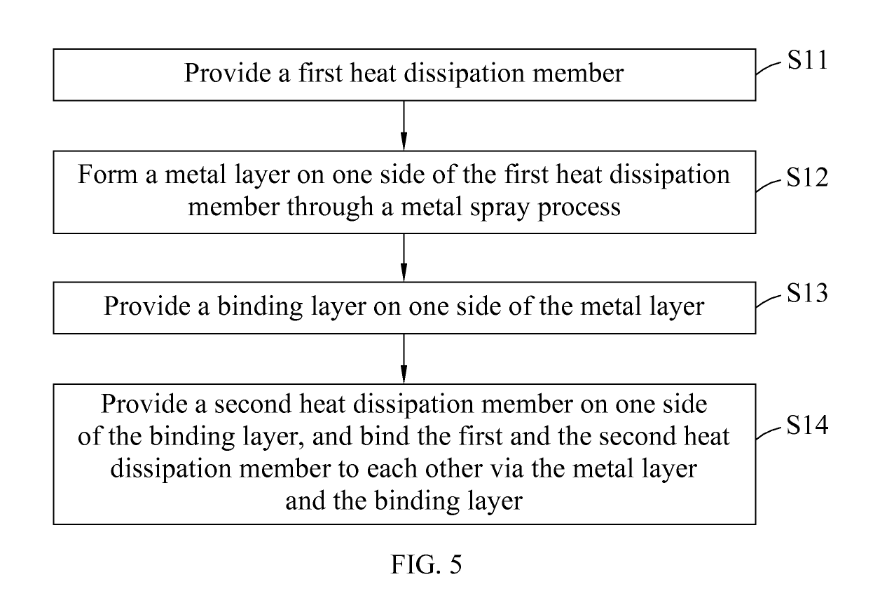

Please refer to FIG. 5 that is a flowchart showing the steps included in a method of manufacturing a thermal module according to the present invention.

In a first step S11 of the thermal module manufacturing method of the present invention, a first heat dissipation member is provided.

In a second step S12, a metal layer is formed on one side of the first heat dissipation member through a metal spray process.

In a third step S13, a binding layer is provided on one side of the metal layer opposite to the first heat dissipation member.

In a fourth step S14, a second heat dissipation member is provided on one side of the binding layer opposite to the metal layer, and then, bind the first and the second heat dissipation member to each other via the metal layer and the binding layer.

In the thermal module manufacturing method of the present invention, the first heat dissipation member can be a heat dissipating substrate made of an aluminum metal material. The metal layer can be formed of a copper metal material, a copper alloy material, a nickel metal material, a nickel alloy material, or a copper-nickel alloy material. The metal layer is formed on one side of the first heat dissipation member through a metal spray process. For example, the metal layer can be coated on one side of the first heat dissipation member by vacuum plasma spray (VPS), arc melting spray, wire flame spray, powder flame spray, high velocity oxygen-fuel (HOVF) spray, or atmosphere plasma spray (APS), so that a coating about 1 μm to 1000 μm in thickness is formed.

In the method of the present invention, the binding layer can be a low-temperature solder paste having, but not limited to, a working temperature ranged between 120° C. and 220° C.

In the method of the present invention, the second heat dissipation member can be a heat pipe, which is a round heat pipe made of a copper material usually having, but not limited to, a diameter from 6 mm to 8 mm, and is bent and flattened using a mold or a tool for disposing in a corresponding groove formed on the first heat dissipation member. The heat pipe has a vacuum internal space and contains a small amount of water vapor or condensed water. Via the vaporization and condensation of water vapor in the heat pipe, heat produced by an electronic element can be quickly transferred to a radiating fin assembly via the heat pipe.

In brief, the thermal module of the present invention and the method of manufacturing the same provide the following benefits:

(1) The metal layer is coated on the first heat dissipation member through a metal spray process, which is a dry process and can therefore reduce the production of environmentally hazardous pollutants in the manufacturing process of the thermal module.

(2) The metal layer is formed of a copper metal material or a nickel-aluminum alloy material, which has heat conductivity higher than the conventional electroplated nickel and can therefore increase the heat transfer ability of the thermal module.

(3) The metal spray process can be performed at a cost lower than the nickel electroplating process, and can therefore effectively reduce the manufacturing cost of the thermal module.

(4) The copper metal material or the copper-nickel alloy material for forming the metal layer of the present invention has metal binding ability higher than that of the conventional electroplated nickel, and can therefore provide upgraded heat transfer ability and pull strength to increase the reliability of the thermal module in use.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A thermal module, comprising:
a first heat dissipation member;
a second heat dissipation member; and
a metal layer being provided between the first and the second heat dissipation member, and having a thickness ranged between 1 μm and 1000 μm.

2. The thermal module as claimed in claim 1, wherein the first heat dissipation member is a heat dissipating substrate.

3. The thermal module as claimed in claim 2, wherein the heat dissipating substrate is made of an aluminum metal material.

4. The thermal module as claimed in claim 1, wherein the second heat dissipation member is selected from the group consisting of a heat dissipating substrate and a heat pipe.

5. The thermal module as claimed in claim 4, wherein the heat pipe is made of a copper metal material.

6. The thermal module as claimed in claim 1, wherein the metal layer is formed of a material selected from the group consisting of a copper metal material, a copper alloy, a nickel metal material, a nickel alloy, and a copper-nickel alloy.

7. The thermal module as claimed in claim 1, further comprising a binding layer provided between the second heat dissipation member and the metal layer for binding the second heat dissipation member to the metal layer.

8. The thermal module as claimed in claim 7, wherein the binding material comprises a solder paste.

9. The thermal module as claimed in claim 1, further comprising a radiating fin assembly arranged on one side of the first heat dissipation member.

10. The thermal module as claimed in claim 1, further comprising a cooling fan arranged at one side of the first heat dissipation member.

11. A method of manufacturing a thermal module, comprising the steps of
providing a first heat dissipation member;
providing a metal layer on one side of the first heat dissipation member through a metal spray process;
providing a binding layer on one side of the metal layer opposite to the first heat dissipation member; and
providing a second heat dissipation member on one side of the binding layer opposite to the metal layer, and binding the first and the second heat dissipation member to each other via the metal layer and the binding layer.

12. The method of manufacturing a thermal module as claimed in claim 11, wherein the metal spray process is selected from the group consisting of a vacuum plasma spray (VPS), an arc melting spray, a wire flame spray, a powder flame spray, a high velocity oxygen-fuel (HOVF) spray, and an atmosphere plasma spray (APS).

13. The method of manufacturing a thermal module as claimed in claim 11, wherein the metal layer has a thickness ranged between 1 μm and 1000 μm.

14. The method of manufacturing a thermal module as claimed in claim 11, wherein the first heat dissipation member is a heat dissipating substrate.

15. The method of manufacturing a thermal module as claimed in claim 14, wherein the heat dissipating substrate is made of an aluminum metal material.

16. The method of manufacturing a thermal module as claimed in claim 11, wherein the second heat dissipation member is selected from the group consisting of a heat dissipating substrate and a heat pipe.

17. The method of manufacturing a thermal module as claimed in claim 16, wherein the heat pipe is made of a copper metal material.

18. The method of manufacturing a thermal module as claimed in claim 11, wherein the metal layer is formed of a material selected from the group consisting of a copper metal material, a copper alloy, a nickel metal material, a nickel alloy, and a copper-nickel alloy.

19. The method of manufacturing a thermal module as claimed in claim 11, wherein the binding layer binding material comprises a solder paste.
